(19) United States
(12) Patent Application Publication
(10) Pub. No.: US 2022/0246194 A1
(43) Pub. Date: Aug. 4, 2022

(54) FLASH MEMORY STORAGE APPARATUS AND A BIASING METHOD THEREOF, WHICH CAN REDUCE A GATE INDUCED DRAIN LEAKAGE (GIDL) AND IMPROVE RELIABILITY OF MEMORY CELLS

(71) Applicant: Powerchip Semiconductor Manufacturing Corporation, Hsinchu (TW)

(72) Inventors: Chien-Hung Lien, Chiayi City (TW); Chih-Yuan Wang, Hsinchu County (TW)

(73) Assignee: Powerchip Semiconductor Manufacturing Corporation, Hsinchu (TW)

(21) Appl. No.: 17/204,955

(22) Filed: Mar. 18, 2021

(30) Foreign Application Priority Data
Feb. 4, 2021 (TW) 110104200

(51) Int. Cl. G11C 11/408; G11C 11/4094; G11C 11/4074

(52) U.S. Cl. CPC G11C 11/4085; G11C 11/4074; G11C 11/4094

(57) ABSTRACT

A flash memory storage apparatus includes a memory cell array and a voltage generating circuit. The memory cell array includes at least one memory cell string coupled between a bit line and a source line and including memory cells; each memory cell is coupled to a corresponding word line. The voltage generating circuit is coupled to the memory cell array and configured to output a bias voltage to the word line. A first voltage is applied to a selected word line. A second voltage and a third voltage are applied to unselected second and third word lines, respectively. The first voltage is greater than the second voltage, and the second voltage is greater than the third voltage. The second word line and the third word line are located on two sides of the first word line. A biasing method of a flash memory storage apparatus is also provided.

### CROSS-REFERENCE TO RELATED APPLICATION

This application claims the priority of Taiwan patent application serial no. 110104200, filed on Feb. 4, 2021. The entirety of the above-mentioned patent application is hereby incorporated by reference and made a part of this specification.

### BACKGROUND

### Technical Field

The disclosure relates to a memory storage apparatus and an operating method thereof, and particularly relates to a flash memory storage apparatus and a biasing method thereof.

### Description of Related Art

With the evolution of electronic technologies, electronic apparatuses have become indispensable tools in people's lives. Flash memories which can perform long-term data storage functions and have large storage capacity have become important data storage media. The flash memory contains a plurality of flash memory cell strings. As the demands for data storage increase, the number of flash memory cells included in the flash memory cell string also increases. However, during programming, gate induced drain leakage (GIDL) affects the state of data stored in the flash memory cells, leading to the reduction of reliability of the flash memory cells.

### SUMMARY

The disclosure provides a flash memory storage apparatus and a biasing method thereof, which can reduce a gate induced drain leakage (GIDL) and improve reliability of memory cells.

According to an embodiment of the disclosure, a flash memory storage apparatus includes a memory cell array and a voltage generating circuit. The memory cell array includes at least one memory cell string. The memory cell string is coupled between a bit line and a source line. The memory cell string includes a plurality of memory cells, and each of the memory cells is coupled to a corresponding word line. The voltage generating circuit is coupled to the memory cell array. The voltage generating circuit is configured to output a bias voltage to the word lines. A first voltage is applied to a selected first word line of the word lines. Unselected word lines include a second word line and a third word line, and a second voltage and a third voltage are applied to the second word line and the third word line, respectively. The first voltage is greater than the second voltage, and the second voltage is greater than the third voltage. The second word line and the third word line are respectively located on two sides of the first word line.

In an embodiment of the disclosure, the second word line is located at a source side area between the first word line and the source line. The third word line located at a drain side area between the first word line and the bit line.

In an embodiment of the disclosure, the second word line is the unselected word line located in the source side area and closest to the first word line, and the second voltage is applied to the second word line. A fourth voltage is applied to all the other unselected word lines in the source side area. The fourth voltage is less than the second voltage but greater than the third voltage.

In an embodiment of the disclosure, the third word line is the unselected word line located in the drain side area and closest to the first word line, and the third voltage is applied to the third word line. A fourth voltage is applied to all the other unselected word lines in the drain side area. The fourth voltage is less than the second voltage but greater than the third voltage.

In an embodiment of the disclosure, the third voltage is applied to all other unselected word lines in the drain side area.

In an embodiment of the disclosure, a system voltage is applied to the bit line and source line.

In an embodiment of the disclosure, the flash memory storage apparatus is a NAND gate flash memory.

According to an embodiment of the disclosure, a biasing method of a flash memory storage apparatus includes: applying a first voltage to a selected first word line among word lines; applying a second voltage to an unselected second word line of the word lines and applying a third voltage to an unselected third word line of the word lines. The first voltage is greater than the second voltage, and the second voltage is greater than the third voltage. The second word line and the third word line are located on two sides of the first word line, respectively.

In an embodiment of the disclosure, the second word line is located at a source side area between the first word line and the source line. The third word line is located at a drain side area between the first word line and the bit line.

In an embodiment of the disclosure, the source side area includes a plurality of unselected word lines, and the second voltage is applied to the second word line located in the source side area and closest to the first word line.

In an embodiment of the disclosure, the biasing method of the flash memory storage apparatus further includes: applying a fourth voltage to the unselected word lines other than the second word line in the source side area. The fourth voltage is less than the second voltage but greater than the third voltage.

In an embodiment of the disclosure, the drain side area includes a plurality of unselected word lines, and the third voltage is applied to the third word line located in the drain side area and closest to the first word line.

In an embodiment of the disclosure, the biasing method of the flash memory storage apparatus further includes: applying a fourth voltage to the unselected word lines other than the third word line in the drain side area. The fourth voltage is less than the second voltage but greater than the third voltage.

In an embodiment of the disclosure, the drain side area includes a plurality of unselected word lines, and the third voltage is applied to all other unselected word lines.

In an embodiment of the disclosure, the biasing method of the flash memory storage apparatus further includes: applying a system voltage to the bit line and the source line.

In view of the above, in one or more embodiments of the disclosure, the voltage generating circuit applies bias voltages of different values to the word lines, so as to reduce the GIDL and improve the reliability of the memory cells.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram briefly illustrating a flash memory storage apparatus according to an embodiment of the disclosure.

FIG. 2 is a schematic diagram briefly illustrating the memory cell string according to the embodiment depicted in FIG. 1.

FIG. 3 is a schematic diagram briefly illustrating a bias voltage applied to each driver line in a memory cell array according to an embodiment of the disclosure.

FIG. 4 is a schematic diagram briefly illustrating a bias voltage applied to each driver line in a memory cell array according to another embodiment of the disclosure.

FIG. 5 is a flow chart illustrating steps of a biasing method of a flash memory storage apparatus according to an embodiment of the disclosure.

### DESCRIPTION OF THE EMBODIMENTS

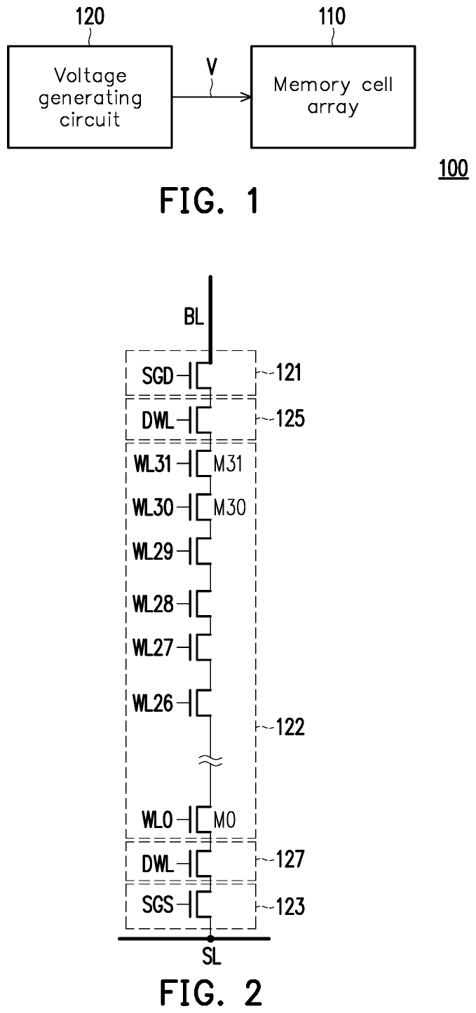

FIG. 1 is a schematic diagram briefly illustrating a flash memory storage apparatus according to an embodiment of the disclosure. FIG. 2 is a schematic diagram briefly illustrating the memory cell string according to the embodiment depicted in FIG. 1. With reference to FIG. 1 and FIG. 2, a flash memory storage apparatus 100 provided in the embodiment includes a memory cell array 110 and a voltage generating circuit 120. The voltage generating circuit 120 is coupled to the memory cell array 110. In this embodiment, the flash memory storage apparatus 100 is, for instance, a NAND gate flash memory. The voltage generating circuit 120 may have a circuit design method well known to those skilled in the art.

The memory cell array 110 includes a bit line BL, a source line SL, and word lines WL0 to WL31. The memory cell array 110 further includes at least one memory cell string 122. The memory cell string 122 is coupled between the bit line BL and the source line SL. The memory cell string 122 includes a plurality of memory cells M0 to M30 and M31. The memory cells M0 to M30 and M31 are coupled to the corresponding word lines WL0 to WL30 and WL31. For instance, the memory cell M31 is coupled to the word line WL31, and the memory cell MO is coupled to the word line WL0. The coupling relationship between other memory cells and their corresponding word lines may be deduced from FIG. 2 and thus will not be further described hereinafter. In addition, the number of the memory cell string, the number of the memory cells, and the number of the word lines do not serve to pose any limitation in the disclosure.

In this embodiment, the memory cell array 110 further includes selection transistors 121 and 123, which are respectively coupled to the corresponding selection lines SGD and SGS. The memory cell string 122 is coupled between the selection transistors 121 and 123. The selection transistors 121 and 123 are configured to select the memory cell string to be programmed during programming. In this embodiment, the memory cell array 110 further includes dummy memory cells 125 and 127, which are respectively coupled to the corresponding dummy word lines DWL. In an embodiment, the memory cell array 110 may not include any dummy memory cell nor any dummy word line.

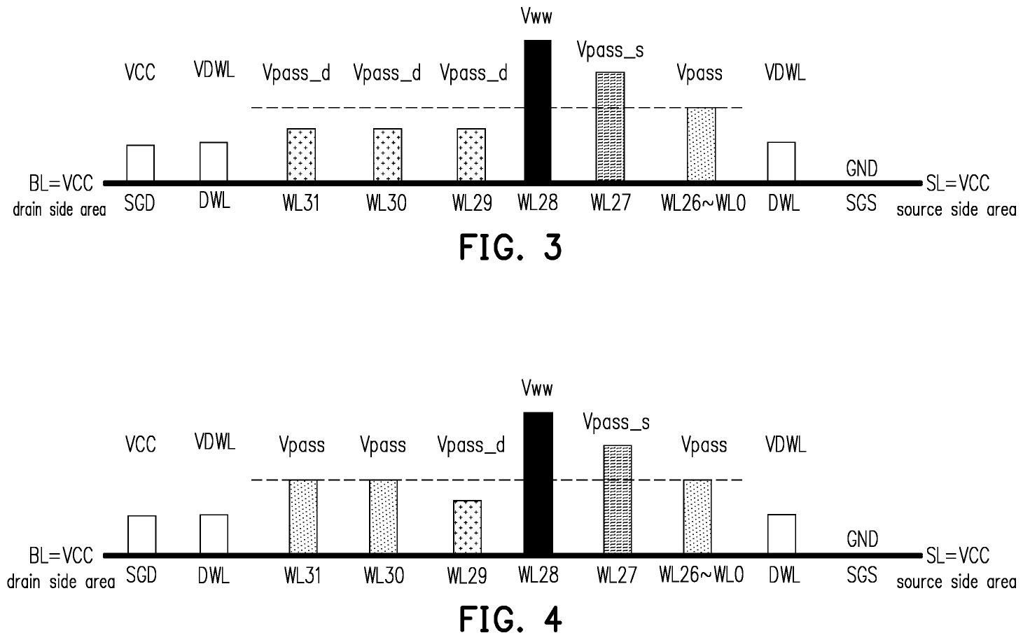

FIG. 3 is a schematic diagram briefly illustrating a bias voltage applied to each driver line in a memory cell array according to an embodiment of the disclosure. With reference to FIG. 1 to FIG. 3, the voltage generating circuit 120 is configured to output a bias voltage V to the word lines WL0 to WL31 during the programming period. The bias voltage V includes a first voltage Vww, a second voltage Vpass_s, a third voltage Vpass_d, and a fourth voltage Vpass. The first voltage Vww is greater than the second voltage Vpass_s, and the second voltage Vpass_s is greater than the third voltage Vpass_d. The fourth voltage Vpass is less than the second voltage Vpass_s but is greater than the third voltage Vpass_d. In this embodiment, the first voltage Vww is applied to the selected word line WL28 (the first word line) of the word lines WL0 to WL31, and the second voltage Vpass_s and the third voltage Vpass_d are applied to the unselected word lines WL27, WL29 to WL31. In FIG. 3, the vertical height of the histogram represents the voltage applied to each driver line.

Specifically, among the word lines WL0 to WL31, the word line WL28 is, for instance, the selected word line. The other word lines WL0 to WL27 (the second word lines) and word lines WL29 to W31 (the third word lines) are unselected word lines. In this embodiment, compared to the first word line WL28, the second word lines WL0 to WL27 are located closer to the source line SL, wherein the word line WL27 is located closest to the first word line WL28. Compared to the first word line WL28, the third word lines WL29 to W31 are located closer to the bit line BL, wherein the word line WL29 is located closest to the first word line WL28.

In this embodiment, the second voltage Vpass_s is applied to the second word line WL27 located closest to the first word line WL28, and the fourth voltage Vpass is applied to the other second word lines WL0 to WL26; here, the fourth voltage Vpass is less than the second voltage Vpass_s. In this embodiment, since the voltage generating circuit 120 applies the second voltage Vpass_s to one single second word line WL27 located in a source side area and closest to the first word line WL28, and the second voltage Vpass_s is greater than the fourth voltage Vpass, the programming speed may be improved. In this embodiment, the second voltage Vpass_s is applied only to one single second word line WL27 located closest to the first word line WL28, which should however not be construed as a limitation in the disclosure. In an embodiment, the voltage generating circuit 120 may also apply the second voltage Vpass_s to one or more second word lines between the source line SL and the first word line WL28.

On the other hand, in this embodiment, the third voltage Vpass_d is applied to the third word lines WL29 to W31 between the bit line BL and the first word line WL28. Since the voltage generating circuit 120 provided in this embodiment applies the third voltage Vpass_d to all the third word lines WL29 to W31 in a drain side area, the gate induced drain leakage (GIDL) of the drain side area may be reduced.

In addition, in this embodiment, during the programming period, a system voltage VCC is applied to the bit line BL, the source line SL, and the selection line SGD, a ground voltage GND is applied to the selection line SGS, and a dummy voltage VDWL is applied to the dummy word line DWL. According to this embodiment, the system voltage VCC is equal to the dummy voltage VDWL, and the system voltage VCC is less than the third voltage Vpass_d. The system voltage VCC and the dummy voltage VDWL may be supplied by the voltage generating circuit 120 or other circuits in the apparatus.

In this embodiment, the third voltage Vpass_d is applied to all the third word lines WL29 to W31 between the bit line BL and the first word line WL28, which should however not be construed as a limitation in the disclosure. In an embodiment, the voltage generating circuit 120 may also apply the third voltage Vpass_d only to at least one third word line.

FIG. 4 is a schematic diagram briefly illustrating a bias voltage applied to each driver line in a memory cell array according to another embodiment of the disclosure. With reference to FIG. 1, FIG. 2, and FIG. 4, in this embodiment, the third voltage Vpass_d is applied to the third word line WL29 closest to the first word line WL28, and the fourth voltage Vpass is applied to the other third word lines WL30 and WL31 to reduce the GIDL of the drain side area.

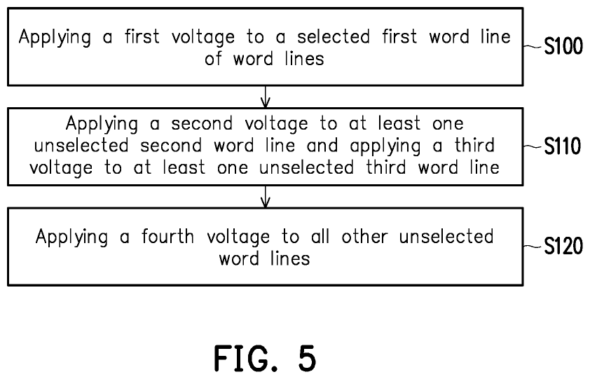

FIG. 5 is a flow chart illustrating steps of a biasing method of a flash memory storage apparatus according to an embodiment of the disclosure. With reference to FIG. 1 to FIG. 3 and FIG. 5, the operating method provided in this embodiment is at least adapted to the flash memory storage apparatus 100 depicted in FIG. 1, which should however not be construed as a limitation in the disclosure. The flash memory storage apparatus 100 depicted in FIG. 1 is taken as an example; in step S100, the voltage generating circuit 120 applies the first voltage Vww to the selected first word line WL28 of the word lines. In step S110, the voltage generating circuit 120 applies the second voltage Vpass_s to at least one unselected second word line WL27 and applies the third voltage Vpass_d to at least one unselected third word line WL29. In step S120, the voltage generating circuit 120 applies the fourth voltage Vpass to all other unselected word lines. The first voltage Vww is greater than the second voltage Vpass_s, and the second voltage Vpass_s is greater than the third voltage Vpass_d. The fourth voltage Vpass is less than the second voltage Vpass_s but is greater than the third voltage Vpass_d. In addition, the teachings, suggestions, and implementations of the biasing method provided in this embodiment may be sufficiently obtained from the descriptions of the embodiments depicted in FIG. 1 to FIG. 4 embodiments.

To sum up, in one or more embodiments of the disclosure, the voltage generating circuit outputs an asymmetric bias voltage to the unselected word lines adjacent to the selected word line during programming, which not only reduces the GIDL and improves the reliability of the memory cells but also increases the programming speed.

It will be apparent to those skilled in the art that various modifications and variations can be made to the disclosed embodiment without departing from the scope or spirit of the disclosure. In view of the foregoing, it is intended that the disclosure covers modifications and variations, provided that they fall within the scope of the following claims and their equivalents.

1. A flash memory storage apparatus, comprising:
a memory cell array, comprising at least one memory cell string coupled between a bit line and a source line, wherein the at least one memory cell string comprises a plurality of memory cells, and each of the memory cell is coupled to a corresponding word line; and
a voltage generating circuit, coupled to the memory cell array and outputting a bias voltage to the word lines, wherein a first voltage of the bias voltage is applied to a selected first word line of the word lines, unselected word lines comprise a second word line and a third word line, a second voltage of the bias voltage and a third voltage of the bias voltage are applied to the second word line and the third word line, respectively, a value of the first voltage is greater than a value of the second voltage, the value of the second voltage is greater than a value of the third voltage, and the second word line and the third word line are respectively located on two sides of the first word line,
wherein the second word line is located at a source side area between the first word line and the source line, and the third word line is located at a drain side area between the first word line and the bit line,
wherein the third word line is the unselected word line located in the drain side area and closest to the first word line, and a fourth voltage of the bias voltage is applied to all unselected word lines in the drain side area except for the third word line, wherein a value of the fourth voltage is less than the value of the second voltage but greater than the value of the third voltage.

2. (canceled)

3. The flash memory storage apparatus according to claim 1, wherein the second word line is the unselected word line located in the source side area and closest to the first word line, and the fourth voltage is applied to all unselected word lines in the source side area except for the second word line.

4. (canceled)

5. The flash memory storage apparatus according to claim 1, wherein the third voltage is applied to all other unselected word lines in the drain side area.

6. The flash memory storage apparatus according to claim 1, wherein a system voltage is applied to the bit line and the source line.

7. The flash memory storage apparatus according to claim 1, wherein the flash memory storage apparatus is a NAND gate flash memory.

8. A biasing method of a flash memory storage apparatus, wherein a memory cell array comprises at least one memory cell string coupled to between a bit line and a source line, the at least one memory cell string comprises a plurality of memory cells, and each of the memory cell is coupled to a corresponding word line, the biasing method comprising:
applying a first voltage of a bias voltage to a selected first word line of the word lines; and
applying a second voltage of the bias voltage to an unselected second word line of the word lines and applying a third voltage of the bias voltage to an unselected third word line of the word lines,
wherein a value of the first voltage is greater than a value of the second voltage, the value of the second voltage is greater than a value of the third voltage, and the second word line and the third word line are respectively located on two sides of the first word line,
wherein the second word line is located at a source side area between the first word line and the source line, and the third word line is located at a drain side area between the first word line and the bit line,
wherein the third word line is the unselected word line located in the drain side area and closest to the first word line, and the biasing method of the flash memory storage apparatus further comprises:
applying a fourth voltage of the bias voltage to the unselected word lines other than the third word line in the drain side area, wherein a value of the fourth voltage is less than the value of the second voltage but greater than the value of the third voltage.

9. (canceled)

10. The biasing method of the flash memory storage apparatus according to claim 8, wherein the source side area comprises a plurality of unselected word lines, and the second voltage is applied to the second word line located closest to the first word line.

11. The biasing method of the flash memory storage apparatus according to claim 10, further comprising:
applying the fourth voltage to the unselected word lines other than the second word line in the source side area.

12. The biasing method of the flash memory storage apparatus according to claim 8, wherein the drain side area comprises a plurality of unselected word lines, and the third voltage is applied to the third word line located closest to the first word line.

13. (canceled)

14. The biasing method of the flash memory storage apparatus according to claim 8, wherein the drain side area comprises a plurality of unselected word lines, and the third voltage is applied to all other unselected word lines in the drain side area.

15. The biasing method of the flash memory storage apparatus according to claim 8, further comprising:
applying a system voltage to the bit line and the source line.

16. The biasing method of a flash memory storage apparatus according to claim 8, wherein the flash memory storage apparatus is a NAND gate flash memory.
